(19) United States
(12) Patent Application Publication
(10) Pub. No.: US 2016/0056020 A1
(43) Pub. Date: Feb. 25, 2016

(54) SYSTEMS AND METHODS FOR TREATING MATERIAL SURFACES

(71) Applicant: WASHINGTON STATE UNIVERSITY, Pullman, WA (US)

(72) Inventors: William Pimakouan LEKOBOU, Pullman, WA (US); Karl Richard ENGLUND, Moscow, ID (US); Patrick Dennis PEDROW, Moscow, ID (US); Erik Charles WEMLINGER, Fairmont, WV (US); Rokibul ISLAM, Pullman, WA (US)

(21) Appl. No.: 14/780,492

(22) PCT Filed: Mar. 27, 2014
(86) PCT No.: PCT/US14/32058

§ 371 Date: Sep. 25, 2015

Related U.S. Application Data
(60) Provisional application No. 61/805,740, filed on Mar. 27, 2013.

(51) Int. Cl. H01J 37/32; H05H 1/24; B05D 5/08

(52) U.S. Cl. CPC H01J 37/32073; H01J 37/32541; H01J 37/32715; H01J 37/32816; H01J 37/3244; B05D 5/08; H05H 1/24; H01J 2237/336; H01J 2237/332; H01J 2237/327

(57) ABSTRACT

A system for treating at least one surface of a material may include a reaction vessel containing a first electrode and a second electrode separated by a gap. A power source may generate an electrical potential across the first electrode and the second electrode. A mixture of a non-reactive fluid and a reactive fluid exposed to the electrical potential may produce a back coronal plasma discharge from the second electrode to the first electrode. The reactive gas may further form a treatment material within the plasma. Depending on the reactive fluid introduced in the reaction vessel, a substrate disposed distally with respect to the second electrode may be coated with the treatment material, thereby increasing the hydrophobic character of the substrate. The treated substrate may be incorporated into a composite composition composed of a hydrophobic matrix.

### CLAIM OF PRIORITY

This application claims benefit of and priority to U.S. Provisional Application No. 61/805,740 entitled “Atmospheric Pressure Weakly Ionized Plasma Reactor Based on Back Corona Discharge” filed Mar. 27, 2013, the disclosure of which is incorporated by reference herein in its entirety.

### BACKGROUND

Natural fibers have been used historically as part of composite materials such as the use of straw in mud bricks. Presently, applications for natural fiber composites may be found in construction materials for use in decking, siding, railing, windows and doors, roofs, and automobile parts, as some examples. Such composites may be useful due to their light weight, reasonable strength, and stiffness.

One challenge for achieving high quality plastic composite materials may arise from the incompatibility between the polar or hydrophilic surface of natural fibers, such as those derived from wood, and the non-polar and hydrophobic nature of most commonly used matrixes, such as polyethylene (PE) and polypropylene (PP). Constituents of wood-derived fibers may include cellulose, hemicellulose and lignin. In some wood-derived materials, cellulose may be present in an amount of about 50% by weight and lignin may be present in an amount of about 16% to about 33% by weight. Additional components of wood-derived materials may include fats, fatty acids, and oils, which may constitute about 5% to about 30% by weight of the wood-derived material. Cellulose and hemicellulose are glucose based polymers and may be composed of a significant number of hydroxyl groups. Additionally, fatty acids are composed of carboxylic acid groups. These two types of hydrophilic groups may reduce the effective incorporation of wood-derived fibers into hydrophobic matrix polymers. Therefore, it has been found useful to apply chemical, physical, or electrical treatments to the surfaces of natural fiber materials to render their surface properties more compatible with polymer matrices.

Chemical coupling is an important method in wood plastic composite industry to improve interfacial adhesion between cellulose based fillers and plastics. Coupling agents are substances that can be added in small amounts into a composite formulation to establish a chemical bond with the filler on one end and a chemical bond with the matrix on the other. Physical methods can be used to change the structure or surface properties of fibers, mainly the surface free energy, to promote adhesion with polymers. Some examples of these physical methods may include stretching, calendaring, and heating the fibers. Electrical discharge treatment methods, including methods using corona and cold plasma discharges, may also be efficient for modifying surface properties of materials. Without being bound by theory, the electrical discharge modifications of surface properties of fibers may result in roughening the fiber surface, increasing or decreasing fiber surface chemical groups, or a combination thereof. Electrical discharge methods may also be used to coat the surface of the fiber with a film having properties compatible with the matrix.

Each of the above disclosed methods may have disadvantages. Chemical processes may require the handling, use, storage, and disposal of toxic or environmentally unfriendly chemicals. Physical methods may be useful only for some limited types of fibers. Typical electrical discharge methods may expose the treated fibers to electrically charged species capable of breaking down the chemical structure of the fiber material, thereby compromising the inherent strength of the fibers. It may be appreciated that improved surface treatment processes of natural fibers for integration into polymer composites, which avoid the disadvantages disclosed above, would be highly useful in the composite industry.

### SUMMARY

In an embodiment, a system for treating a substrate may include a reaction vessel having a proximal end and a distal end, a source of a non-reactive fluid in fluid communication with the proximal end of the reaction vessel, a source of a reactive fluid in fluid communication with the proximal end of the reaction vessel, a first electrode disposed within the proximal end of the reaction vessel and comprising at least one needle having a needle tip, in which the at least one needle tip is disposed towards the distal end of the reaction vessel, a second electrode disposed within the reaction vessel and distal to the at least one needle tip, thereby defining a gap between the at least one needle tip and the second electrode, a power supply in electrical communication with the at least one needle tip and the second electrode and configured to produce an electrical potential between the at least one needle tip and the second electrode, and a substrate holder disposed within the reaction vessel and distal to the second electrode.

In an embodiment, a method of treating a substrate may include providing a system for treating a substrate composed of a reaction vessel having a proximal end and a distal end, a source of a non-reactive fluid in fluid communication with the proximal end of the reaction vessel, a source of a reactive fluid in fluid communication with the proximal end of the reaction vessel, a first electrode disposed within the proximal end of the reaction vessel and comprising at least one needle having a needle tip, wherein the at least one needle tip is disposed towards the distal end of the reaction vessel, a second electrode disposed within the reaction vessel and distal to the at least one needle tip, thereby defining a gap between the at least one needle tip and the second electrode, a power supply in electrical communication with the at least one needle tip and the second electrode and configured to produce an electrical potential between the at least one needle tip and the second electrode, and a substrate holder disposed within the reaction vessel and distal to the second electrode. The method may further include contacting the substrate with the substrate holder, introducing a non-reactive fluid into the reaction vessel from the source of the non-reactive fluid, introducing a reactive fluid into the reaction vessel from the source of the reactive fluid, causing the power supply to develop an electrical potential between the first electrode and the second electrode, exposing at least the reactive fluid to the electrical potential, thereby producing a treatment material, and contacting a surface of the substrate with the treatment material, thereby treating the substrate, in which a fluid pressure within the reaction vessel due at least in part to the non-reactive fluid and the reactive fluid therein is about equal to an ambient gas pressure.

In another embodiment, a composition may include a polymer matrix and at least one substrate within the polymer matrix, in which the at least one substrate is coated with a treatment material that includes electrically neutral reactive fluid radicals.

In another embodiment, a method of fabricating a system for treating a substrate may include providing a reaction vessel comprising a proximal interior end and a distal interior end, contacting a first electrode comprising at least one needle having a needle tip within the proximal interior of the reaction vessel, in which the at least one needle tip is directed towards the distal interior end of the reaction vessel, contacting a second electrode within the distal interior end of the reaction vessel, thereby forming a gap between the at least one needle tip and the second electrode, disposing a substrate holder within the distal interior end of the reaction vessel, in which the substrate holder is distal to the second electrode, providing at least one fluid inlet port in fluid communication with the proximal interior end of the reaction vessel, and providing at least one exhaust outlet in fluid communication with the distal interior end of the reaction vessel.

### BRIEF DESCRIPTION OF THE DRAWINGS

FIG. 1 illustrates a system for treating a material surface in accordance with some embodiments.

FIG. 2 is a flow diagram of a method of constructing a system for treating a material surface in accordance with some embodiments.

FIG. 3 illustrates a mechanism whereby a treatment system may treat a material surface in accordance with some embodiments.

FIG. 4 is a flow diagram of a method of treating a material surface in accordance with some embodiments.

FIG. 5 illustrates a material surface having received a treatment in accordance with some embodiments.

### DETAILED DESCRIPTION

Plasma may be composed of gas-phase neutral and charged particles with the charged species generally moving under the influence of macroscopic electric (E) and magnetic (B) fields. When a large electric potential is applied between two electrodes, the macroscopic E and B fields may be generated primarily due to the applied potential. The macroscopic E field may contribute to “mobility drift” of charged species within the plasma, and extremely high E fields may result in impact ionization of neutral plasma species by free electrons. Under suitable conditions, free electrons accelerated in the macroscopic E field may possess sufficiently high kinetic energy to yield not only ionized species but also neutral radicals due to bond scission of some chemical species in the plasma. Materials exposed to plasma or coronal discharges may undergo surface alterations due to surface exposure to the charged and electrically neutral radical species generated under plasma conditions.

Plasma treatments have historically been regarded as out-of-reach for many applications due to costs and processing logistics. Typically, plasma treatment reactors have been operated under low pressure to maximize the efficiency of plasma generation. Low pressure plasma reactors may require a high capital investment in vacuum equipment and may be limited with regard to material shape and type being processed. Plasma reactors generating atmospheric pressure weakly ionized plasma (hereafter, “APWIP”) may be operated at or near ambient pressure, thereby obviating the need for low pressure equipment and techniques. Thus, the use of APWIP reactor systems may generally decrease the economic burden associated with the use of low-pressure reactor systems.

In one non-limiting configuration of an APWIP reactor system, dielectric barrier discharge electrodes may be energized with a radio frequency (RF) electrical power supply. The plasma generated by an APWIP reactor system having dielectric barrier discharge electrodes may include contaminating species derived from breakdown products of the dielectric barrier coating of the electrodes. The APWIP systems and methods disclosed herein, using non-dielectric coated or bare-metal electrodes, may provide improvements over conventional dielectric barrier and other low-pressure systems and methods. The APWIP systems disclosed herein may additionally use a point-to-plane electrode configuration to produce a back coronal discharge. Such back coronal discharges may result in improved deposition of materials on the treated surfaces by producing a more consistent polymer coating on the surface, reducing the treatment time, increasing material throughput through the system, decreasing surface degradation from charged species, and improving the quality of the treated surface.

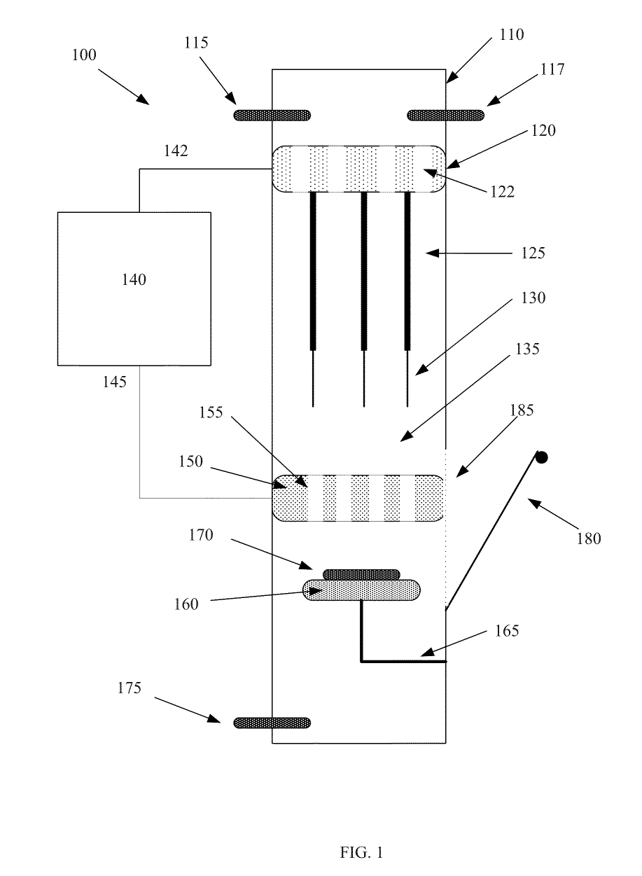

FIG. 1 depicts an embodiment of such an improved APWIP reactor system 100. The treatment system 100 may be composed of a reaction vessel 110 having a proximal end (for example, at the top of FIG. 1) having a proximal interior and a distal end (for example, at the bottom of FIG. 1) having a distal interior. The reaction vessel 110 may have any shape or size suitable for its function. Non-limiting examples of the reaction vessel 110 may include a hollow cylinder, a hollow rectangular prism, a hollow triangular prism, a uniform polyhedral prism, a hollow cone, and a truncated hollow cone. At least a portion of reaction vessel 110 may be composed of a non-conducting material. Non-limiting examples of non-conducting materials may include polyvinyl chloride, poly(methyl methacrylate), poly(tetrafluoro ethylene), a low-thermal-expansion borosilicate glass, quartz, a polycarbonate, poly(oxy methylene), an aliphatic polyamide, polyethylene, or any combination thereof. The reaction vessel 110 may also be sealed at the proximal end, the distal end, or both proximal and distal ends.

In one non-limiting embodiment, the reaction vessel 110 may have an inlet port 115 for a reactive fluid near the proximal end of the reaction vessel and in fluid communication with the proximal interior end of the reaction vessel. The inlet port 115 may be in fluid communication with a source of a reactive fluid such as a gas tank (not shown). Any number or type of regulating valves may be in fluid communication between the source of the reactive fluid and the inlet port 115 to regulate the flow of the reactive fluid from the source to the inlet port. Regulating valves for the reactive fluid may be manually operated or automatically operated under the control of an automated control mechanism. Non-limiting examples of reactive fluids may include a hydrocarbon gas, oxygen gas, sulfur hexafluoride gas, carbon tetrafluoride gas, aniline vapor, hexadimethyldisiloxane vapor, di(ethylene glycol) vinyl ether vapor, or any combination thereof. It may be understood that such reactive fluids may not exist in a gaseous state under ambient temperature and pressure. In some non-limiting examples, some non-gaseous materials may readily be converted to the gas state through heating. In other non-limiting examples, some non-gaseous materials may have a high vapor pressure under ambient conditions, thereby providing a reactive gaseous material without requiring additional thermal input.

In one non-limiting embodiment, the reaction vessel 110 may have an inlet port 117 for a non-reactive fluid near the proximal end of the reaction vessel and in fluid communication with the proximal interior end of the reaction vessel. The inlet port 117 may be in fluid communication with a source of a non-reactive fluid such as a gas tank (not shown). Any number or type of regulating valves may be in fluid communication between the source of the non-reactive fluid and the inlet port 117 to regulate the flow of the non-reactive fluid from the source to the inlet port. Regulating valves for the non-reactive fluid may be manually operated or automatically operated under the control of an automated control mechanism. It may be appreciated that an automated control mechanism to control regulating valves for the non-reactive fluid may be the same automated control mechanism used to control regulating valves for the reactive fluid. Alternatively, regulating valves for the non-reactive fluid and regulating valves for the reactive fluid may be controlled by different control mechanisms. Non-limiting examples of non-reactive fluids may include argon, helium, neon, or any combination thereof.

In some non-limiting embodiments, the reaction vessel 110 may have multiple inlet ports 115 for reactive fluids and multiple inlet ports 117 for non-reactive fluids near the proximal end of the reaction vessel. In some other non-limiting embodiments, the reaction vessel 110 may have a single inlet port to deliver both the reactive fluid and non-reactive fluid near the proximal end of the reaction vessel. In other non-limiting embodiments, the inlet port 115 for a reactive fluid and the inlet port 117 for a non-reactive fluid may each include one or more valves to regulate the amount of reactive fluid and non-reactive fluid, respectively, that enter the reaction vessel 110. In some non-limiting embodiments, valves to regulate the amount of reactive fluid and non-reactive fluid entering the reaction vessel 110 may be under manual control. In other non-limiting embodiments, valves to regulate the amount of reactive fluid and non-reactive fluid entering the reaction vessel 110 may be under automated control. It may be understood that automated control systems to control the regulating valves for the reactive fluid and regulating values for the non-reactive fluid may be the same control system. Alternatively, the automated control systems to control the regulating valves for the reactive fluid and regulating values for the non-reactive fluid may be different control systems.

The reaction vessel 110 may include a first electrode 120 disposed within the proximal interior end of the reaction vessel. The first electrode 120 may contact the proximal interior end of the reaction vessel 110. In one non-limiting embodiment, the first electrode 120 may be affixed within the reaction vessel 110 to form a fluid-tight seal between the first electrode and the proximal interior end of the reaction vessel. The first electrode 120 may be composed of a plurality of conductive needles 130. The conductive needles 130 may have a length of about 1 cm to about 10 cm. In some non-limiting examples, a conductive needle 130 may have a length of about 1 cm, about 2 cm, about 3 cm, about 4 cm, about 5 cm, about 6 cm, about 7 cm, about 8 cm, about 9 cm, about 10 cm, or ranges between any two of these values (including endpoints). In one non-limiting example, the conductive needles 130 may have a length of about 2.54 cm. In some embodiments, the conductive needles 130 may be made of a conductive material such as a metal. The conductive needles 130 may have an electrically conducting tip. In some non-limiting embodiments, the tip ends of the conductive needles 130 may be a bare metal, including, but not limited to, nickel-plated steel. The tip end of the conductive needles 130 may have a radius of curvature of about 30 μm to about 70 μm. Non-limiting examples of a radius of curvature of a needle tip may include about 30 μm, about 40 μm, about 50 μm, about 60 μm, about 70 μm, or ranges between any two of these values (including endpoints). In one non-limiting example, the conductive needles 130 may have a radius of curvature of about 45 μm.

The first electrode 120 may be composed of one or more conductive needles 130. In some embodiments, the first electrode 120 may be composed of about 5 to about 75 conductive needles 130. Non-limiting examples of a number of needles 130 in contact with the first electrode 120 may include about 5 needles, about 10 needles, about 20 needles, about 30 needles, about 40 needles, about 50 needles, about 60 needles, about 70 needles, or ranges between any two of these values (including endpoints). In one example, the first electrode 120 may be composed of about 8 conductive needles 130. The conductive needles 130 may be disposed in a symmetric or asymmetric manner on the first electrode 120. Symmetric patterns may include a single circle, multiple concentric circles, a grid, or any other symmetric geometric pattern. The conductive needles 130 may be disposed on the first electrode 120 with a needle specific area of about 1 cm²/needle to about 65 cm²/needle. A needle specific area may be defined as an area of the surface of first electrode 120 encompassing each conductive needle 130. Non-limiting examples of a needle specific area may include about 1 cm²/needle, about 5 cm²/needle, about 10 cm²/needle, about 15 cm²/needle, about 20 cm²/needle, about 25 cm²/needle, about 30 cm²/needle, about 35 cm²/needle, about 40 cm²/needle, about 45 cm²/needle, about 50 cm²/needle, about 55 cm²/needle, about 60 cm²/needle, about 65 cm²/needle, or ranges between any two of these values (including endpoints). In one example, the conductive needles 130 may be disposed on the first electrode 120 with a needle specific area of about 5 cm²/needle. In some non-limiting embodiments, the conductive needles 130 may be disposed on a surface of the first electrode 120 according to a distance between nearest neighbor conductive needles. In some non-limiting examples, a conductive needle 130 may be spaced apart from its nearest neighbor conductive needle by a distance greater than or equal to about 4 cm. In some non-limiting examples, a conductive needle 130 may be spaced apart from its nearest neighbor conductive needle by a distance greater than or equal to about 3 cm. In yet another non-limiting example, a conductive needle 130 may be spaced apart from its nearest neighbor conductive needle by a distance less than or equal to about 3 cm.

It may be appreciated that the above disclosure with regard to the disposition of the conductive needles 130 with respect to the first electrode 120 may include both conductive needles disposed directly on a conductive surface of the first electrode and conductive needles in electrical communication with conductive needle rods 125 that may be disposed on the first electrode.

In some embodiments, the first electrode 120 may be composed of conductive needles 130 in electrical contact with an electrically conducting surface. The electrically conducting surface may be in physical contact with an inner surface of the reaction vessel 110 near the proximal end of the reaction vessel. In some embodiments, the electrically conducting surface may be a steel disk to which the conductive needles 130 are affixed. In some non-limiting examples, the conductive needles 130 may be in electrical contact with the conductive surface via electrically conductive needle rods 125. The conductive needle rods 125 may be in electrical communication with the conducting surface on one end of the needle rod and a conductive needle on the other end of the conductive needle rod. In some non-limiting examples, the conductive needle rods 125 may have a length of about 1 cm to about 10 cm. In some non-limiting examples, a conductive needle rod 125 may have a length of about 1 cm, about 2 cm, about 3 cm, about 4 cm, about 5 cm, about 6 cm, about 7 cm, about 8 cm, about 9 cm, about 10 cm, or ranges between any two of these values (including endpoints). In one example, the conductive needle rods 125 may each have a length of about 2.5 cm.

In addition to the conductive needles 130 and/or conductive needle rods 125, the first electrode 120 may also incorporate one or more first electrode vents 122. In some embodiments, a first electrode 120 composed of a conductive surface may have the one or more first electrode vents 122 disposed in the conductive surface. Such vents 122 may be placed within the first electrode 120 to permit the reactive fluid and/or the non-reactive fluid to pass from the proximal end of the reaction vessel 110 in a distal manner. The first electrode vents 122 may be disposed in any manner in the first electrode 120, including symmetric or asymmetric placements. The first electrode vents 122 may be disposed in a pattern related to the disposition of the conductive needles 130 and/or needle rods 125 with respect to the first electrode 120.

The treatment system 100 may also include a second electrode 150. The reaction vessel 110 may include a second electrode 150 disposed within the distal interior end of the reaction vessel. It may be understood that the second electrode 150 is disposed distal to first electrode 120. The second electrode 150 may contact the distal interior end of the reaction vessel 110. In one non-limiting embodiment, the second electrode 150 may be affixed within the reaction vessel 110 to form a fluid-tight seal between the second electrode and the distal interior end of the reaction vessel.

The disposition of the first electrode 120 and the second electrode 150 within the reaction vessel 110 may result in a gap 135 between the one or more conductive needles 130 in electrical contact with the first electrode 120 and the second electrode. It may be further understood that the one or more conductive needles 130 in electrical contact with the first electrode 120 are disposed so that the tip end of each of the conductive needles is disposed in a distal direction towards the second electrode 150 at the distal interior end of the reaction vessel 110. The gap 135 may have a gap distance of about 1 cm to about 20 cm as measured from the tip end of the conductive needles 130 to the second electrode 150. In some non-limiting examples, a gap distance may have a length of about 1 cm, about 2 cm, about 4 cm, about 6 cm, about 8 cm, about 10 cm, about 12 cm, about 14 cm, about 16 cm, about 18 cm, about 20 cm, or ranges between any two of these values (including endpoints). In one non-limiting example, the gap 135 may have a gap distance of about 10 cm as measured from the tip end of the conductive needles 130 to the second electrode 150. In some embodiments, the gap distance may be adjusted to optimize the modes of the corona discharge. Examples of modes of corona discharge may include, without limitation, primary streamers, secondary streamers, return streamers, and back corona (or back discharge).

The second electrode 150 may be composed of a conducting material such as a metal. In some non-limiting embodiments, the second electrode 150 may include a ring of conductive material. As one non-limiting example, the second electrode 150 may include a ring having at least one rounded surface disposed in a proximal direction and directed towards the gap 135. In another embodiment, the second electrode 150 may be composed of a conductive mesh. The conductive mesh may be composed of a plurality of electrically conducting wires having a wire diameter of about 200 μm to about 900 μm. In some non-limiting examples, the mesh wires may have a diameter of about 200 μm, about 300 μm, about 400 μm, about 500 μm, about 600 μm, about 700 μm, about 800 μm, about 900 μm, or ranges between any two of these values (including endpoints). A mesh-type second electrode 150 may have a porosity of about 40% to about 90%. In some non-limiting examples, the mesh wires may have a porosity of about 40%, about 50%, about 60%, about 70%, about 80%, about 90%, or ranges between any two of these values (including endpoints). In some non-limiting examples, a mesh-type second electrode 150 may have a porosity of about 40% to about 50%. In some alternative non-limiting examples, a mesh-type second electrode 150 may have a porosity of about 80% to about 90%. In yet another example, a mesh-type second electrode 150 may have a porosity of about 70%. In one further example, a mesh-type second electrode 150 may have a porosity of about 78%. A mesh-type second electrode 150 may include one or more openings 155. It may be understood that the one or more openings 155 may also be provided in a second electrode 150 that lacks a mesh structure. In a non-limiting example, the second electrode 150 may include a second conductive surface in which one or more openings 155 are provided.

As disclosed above, a plasma may be induced by subjecting a fluid to an electrical potential. With respect to the treatment system 100, a plasma may be induced in the reactive fluid, the non-reactive fluid, or any combination of the two in the gap 135 between the conductive needles 130 and the second electrode 150. An electrical potential may be created by a power supply 140 having a first terminal in electrical communication with the tips of the conductive needles 130 (via a first terminal line 142) and a second terminal in electrical communication with the second electrode 150 (via a second terminal line 145). In one embodiment, the power supply 140 may be configured to generate an oscillating potential between the tips of the conductive needles 130 and the second electrode 150. In one non-limiting example, the second electrode 150 may be in electrical communication with the power supply 140 ground, while the tips of the conductive needles 130 may be in electrical communication with the oscillating voltage output of the power supply. The power supply 140 may be configured to generate an oscillating electrical potential of about 1.2 kV RMS to about 15 kV RMS between the tips of the conductive needles 130 and the second electrode 150. In some non-limiting examples, the oscillating electrical potential between the tips of the conductive needles 130 and the second electrode 150 generated by power supply 140 may have an RMS voltage of about 1.2 kV RMS, about 1.5 kV RMS, about 2 kV RMS, about 4 kV RMS, about 6 kV RMS, about 8 kV RMS, about 10 kV RMS, about 12 kV RMS, about 14 kV RMS, about 15 kV RMS, or ranges between any two of these values (including endpoints). In one non-limiting example, the power supply 140 may be configured to generate an electrical potential of about 6 kV RMS between the tips of the conductive needles 130 and the second electrode 150.

The power supply 140 may be configured to generate an oscillating potential between the tips of the conductive needles 130 and the second electrode 150 generally having any frequency. In some non-limiting examples, the oscillating potential may have a frequency of about 50 Hz to about 60 Hz. In one non-limiting example, the power supply 140 may be configured to generate an oscillating potential having a frequency of about 60 Hz. It may be understood that such frequencies are related to industry standard power line frequencies, and may therefore be convenient for use. However, the voltage output of the treatment system power supply 140 may not be limited to industry standard power line frequencies.

The potential supplied by the power supply 140 may be controlled manually or automatically. In one embodiment, the power supply 140 may be controlled automatically by a control system to vary the potential it delivers. The electrical potential between the tips of the conductive needles 130 and the second electrode 150 generated by the power supply 140 may be monitored according to any method known in the electronic arts, such as, for example, by a voltmeter or an ammeter. The characteristics of the electrical potential generated by the power supply 140 may further depend, at least in part, on the gap distance, the type of reactive fluid used, the type of non-reactive fluid used, a desired length of time for substrate exposure to the treatment material generated by the plasma, or any combination thereof.

A substrate 170 to receive a surface treatment may be located on a substrate holder 160 disposed within the distal interior end of the reaction vessel 110 and distal to the second electrode 150. The substrate holder 160 may place the substrate 170 at a distance distal from the second electrode 150. The distance of the substrate 170 from the second electrode 150 may be about 0.5 cm to about 5 cm. Non-limiting examples of the distance of the substrate 170 from the second electrode 150 may be about 0.5 cm, about 1 cm, about 1.5 cm, about 2 cm, about 2.5 cm, about 3 cm, about 3.5 cm, about 4 cm, about 4.5 cm, about 5 cm, or ranges between any two of these values (including endpoints). In one non-limiting example, the distance of the substrate 170 from the second electrode 150 may be about 1 cm. In some alternative embodiments, the distance of the substrate 170 from the second electrode 150 may be determined, at least in part, by the lifetime of electrically neutral reactive fluid radicals generated by the plasma. The lifetime of electrically neutral reactive fluid radicals may depend, at least in part, on the density of radicals generated in the plasma, the type of radicals generated, and the transport or drift rate of the radicals from the plasma.

The substrate holder 160 may be stabilized by a stand 165 with respect to the second electrode 150. The stand 165 may be static or may incorporate a motion system to move the substrate holder 160 relative to the second electrode 150. The motion system may move the substrate holder 160 in a vertical direction, a horizontal direction, or any combination of the two. The motion system may be manually operated or may be automatically operated by a motion control system. In one non-limiting example, the motion control system may include a computerized system composed of one or more processing units, one or more static memory devices, one or more dynamic memory devices, one or more input interfaces to receive operator commands or data from sensors associated with the motion system, one or more output interfaces to transmit data to the motion system or provide output perceivable by an operator on one or more operator interface devices, and one or more bus structures to convey data among one or more of the other components. The motion system may receive motion commands from an operator, may include instructions to effect motion commands contained in the static and/or dynamic memory devices, or any combination of the two.

Additionally, the reaction vessel 110 may include a sealable access opening 180 proximate to the sample holder 160. Such an access opening 180 may permit a sample to be contacted with or removed from the sample holder 160.

The treatment system 100 may further include an exhaust outlet 175 proximate to the distal end of the reaction vessel 110 and provide a fluid pathway of fluid or gaseous materials from the distal interior of the reaction vessel. In some embodiments, the exhaust outlet 175 may be vented to atmosphere. In other embodiments, the exhaust outlet 175 may provide a fluid pathway to one or more receptacles for capturing the fluid or gaseous materials from the reaction vessel 110 for disposal, analysis, recycling, or any combination thereof. In another embodiment, the exhaust outlet 175 may be in fluid communication with a pump.

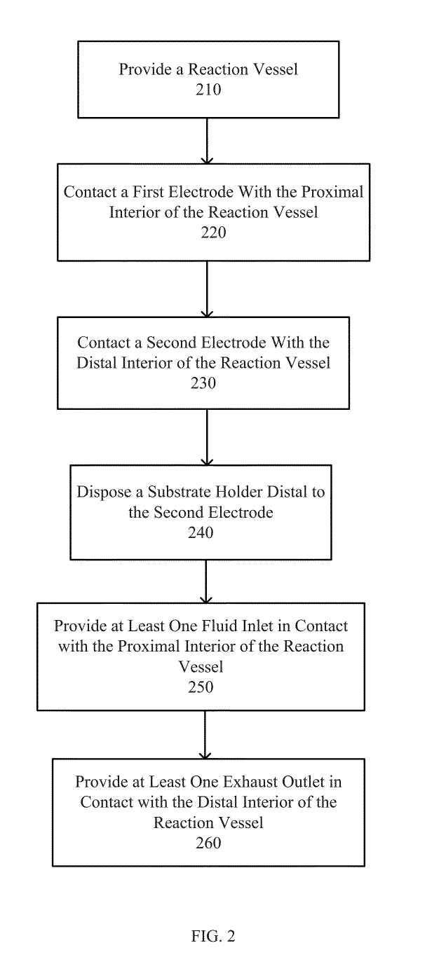

FIG. 2 is a flow chart of a method for fabricating a treatment system, such as disclosed in the embodiments above and depicted in FIG. 1. The treatment system may be fabricated by providing 210 a reaction vessel having a proximal interior end and a distal interior end. A first electrode may be contacted 220 with the proximal interior of the reaction vessel. The first electrode may incorporate at least one conductive needle that is placed within the reaction vessel with the tip of the at least one needle directed towards the distal interior end of the reaction vessel. A second electrode may be contacted 230 with the distal interior of the reaction vessel in a manner to create a gap between the tip of the at least one needle and the second electrode. A substrate holder may be disposed 240 within the distal interior end of the reaction vessel at a position distal to the second electrode. At least one fluid inlet in fluid communication with the proximal interior end of the reaction vessel may be provided 250. At least one exhaust outlet in fluid communication with the distal interior end of the reaction vessel may be provided 260.

Surface treatment of substrate surfaces may be accomplished by exposing the substrate surface to reactive components generated by an atmospheric pressure weakly ionized plasma (APWIP). Such reactive components may be generated in a plasma formed from non-reactive and one or more reactive gases that are exposed to an electric potential. Without being bound by theory, the plasma formation may be initiated by electron avalanches that may occur due to collisions between electrons emitted by an electrode and a gas molecule. Under conditions in which non-reactive gas molecules are more abundant than reactive gas molecules, such collisions may result in the ionization of some of the non-reactive gas molecules and emission of secondary electrons. Both the incident and the secondary electron can gain sufficient kinetic energy from the E field of the electric potential and undergo similar impact ionization with other gas molecules. The multiple impacts of electrons may result in an exponential production of electrons. These avalanches can yield sufficiently large charge separation and associated “Poisson fields” to form self-propagating thin plasma channels called streamers. Reactive gas molecules in the streamers may undergo electron collisions leading to reactive molecule bond scission and resulting in reactive treatment species.

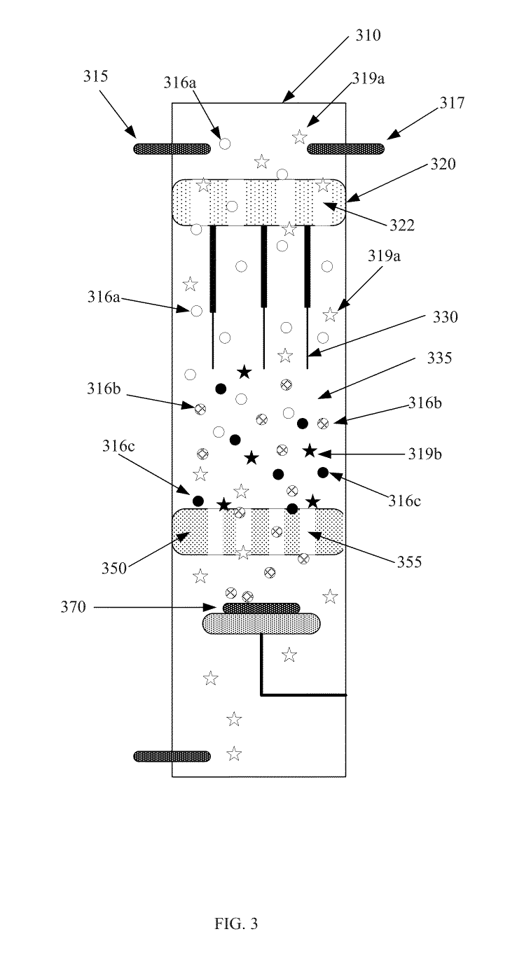

FIG. 3 depicts various reactive species that may be produced under APWIP conditions. Within a reaction chamber 310, a first electrode 322 including at least one conductive needle 330 and a second electrode 350 may be disposed to produce a gap 335 between the tip of the at least one conductive needle and the second electrode. The first electrode 322 is depicted including a plurality of conductive needles 330. An electric potential placed across the needles 330 and the second electrode 350 may result in an electric field between the needles and the second electrode having a high energy density near the needle tips. Neutral reactive fluid molecules 316a may be introduced via a first fluid inlet 315 into the proximal end of the reaction vessel 310, and neutral non-reactive fluid atoms 319a may similarly be introduced via a second fluid inlet 317. Both neutral reactive fluid molecules 316a and neutral non-reactive fluid atoms 319a may pass through one or more vents 322 in the first electrode 320 due to fluid flow.

Once the neutral non-reactive fluid atoms 319a enter the gap 335, they may enter the electric field generated between the tips of the conductive needles 330 and the second electrode 350. Electrons liberated by electron avalanche processes and streamers may impact the neutral non-reactive fluid atoms 319a producing non-reactive fluid ions 319b. Under appropriate conditions of electrical potential, the non-reactive fluid atoms 319a may emit electrons upon ionization, thereby creating the electron avalanche disclosed above.

The neutral reactive fluid molecules 316a may similarly enter the gap 335 and become exposed to the electron avalanche. Under some conditions, electron collisions with the neutral reactive fluid molecules 316a may result in a variety of ionized reactive fluid molecules 316c. Under other conditions, electron collisions with the neutral reactive fluid molecules 316a may result in chemical bond scission resulting in electrically neutral reactive fluid radicals 316b. It may be understood that the electrically neutral reactive fluid radicals 316b do not carry an electrical charge, but include unpaired electrons, thereby making them chemically reactive.

The combination of the neutral non-reactive fluid atoms 319a, the ionized non-reactive fluid atoms 319b, the neutral reactive fluid molecules 316a, the ionized reactive fluid molecules 316c, and the electrically neutral reactive fluid radicals 316b may traverse the gap 335 to the second electrode 350. Ionized species, such as the ionized non-reactive fluid atoms 319b and the ionized reactive fluid molecules 316c may be electrostatically attracted to the second electrode 350 where they become neutralized forming their respective neutral species (319a and 316a, respectively). The neutral species 319a and 316a may traverse openings 355 of the second electrode 350. In addition, the electrically neutral reactive fluid radicals 316b also may traverse the openings 355 because they are not electrostatically directed towards the second electrode 350. The electrically neutral reactive fluid radicals 316b may then interact with the surface of the substrate 370, which is distal to the second electrode 350. The electrically neutral reactive fluid radicals 316b may act as a treatment material of the surface of the substrate 370.

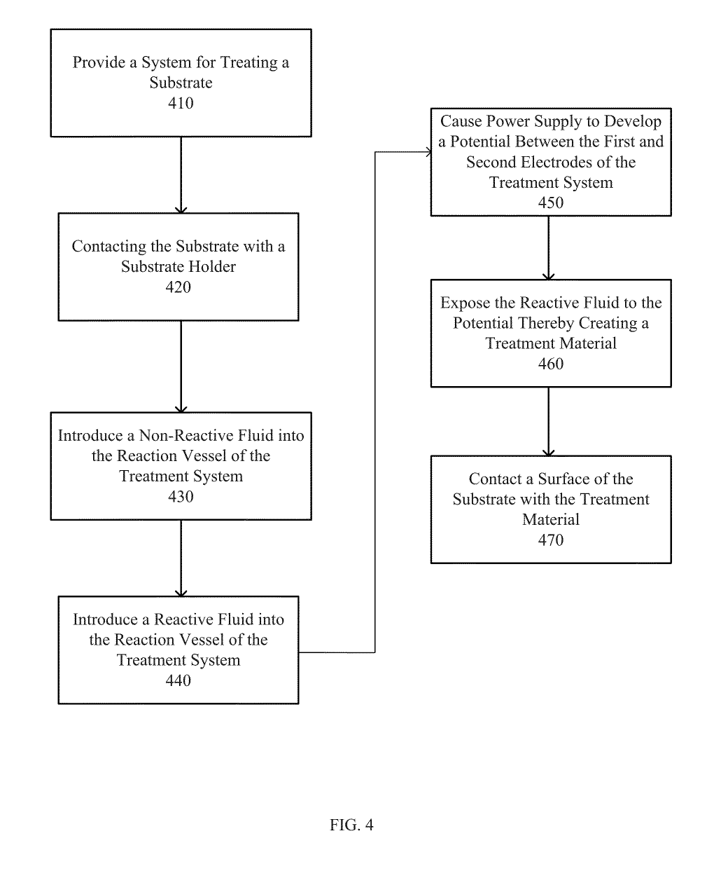

FIG. 4 is a flow chart of a method for treating a surface of a substrate with a treatment material. One embodiment of the method may include providing 410 a treatment system as disclosed above. A substrate to be treated may be contacted 420 with a substrate holder provided in the treatment system. Non-limiting examples of substrates that may be treated may include wood fibers, wood saw dust, cellulose fibers, silk fibers, an organic material, a metal, a ceramic, a polymer, a cellulosic nanocrystal, a nanoparticle, an asphalt road surface, a concrete surface, a paper, a textile, a thread, a yarn, a crop seed, and any combination thereof.

A non-reactive fluid may be introduced 430 into the treatment system reaction vessel from a source of the non-reactive fluid. The non-reactive fluid may include any one or more of argon, helium, neon, or any combination thereof. The non-reactive fluid may be introduced at a rate of about 10 standard cm³/min (sccm) to about 50,000 sccm. Non-limiting examples of a rate of introduction of the non-reactive fluid may include about 10 sccm, about 20 sccm, about 50 sccm, about 100 sccm, about 200 sccm, about 500 sccm, about 1,000 sccm, about 2,000 sccm, about 5,000 sccm, about 10,000 sccm, about 20,000 sccm, about 34,000 sccm, about 50,000 sccm, or ranges between any two of these values (including endpoints). In one non-limiting example, the non-reactive fluid may be introduced into the reaction vessel at a rate of about 34,000 sccm.

A reactive fluid may be introduced 440 into the treatment system reaction vessel from a source of the reactive fluid. The reactive fluid may include any one or more of a hydrocarbon gas, oxygen gas, sulfur hexafluoride gas, carbon tetrafluoride gas, aniline vapor, hexadimethyldisiloxane vapor, di(ethylene glycol) vinyl ether vapor, or any combination thereof. In one non-limiting example, the reactive fluid may include acetylene. The reactive fluid may be introduced at a rate of about 1 sccm to about 1,000 sccm. Non-limiting examples of a rate of introduction of the reactive fluid may include about 1 sccm, about 2 sccm, about 5 sccm, about 10 sccm, about 20 sccm, about 50 sccm, about 100 sccm, about 200 sccm, about 500 sccm, about 1000 sccm, or ranges between any two of these values (including endpoints). In one non-limiting example, the reactive fluid may be introduced into the reaction vessel at a rate of about 10 sccm. In another non-limiting example, the reactive fluid may be introduced into the reaction vessel at a rate of about 116 sccm.

In one non-limiting example, the non-reactive fluid and the reactive fluid may be introduced into the reaction vessel of the treatment system at a total flow rate of about 11 sccm to about 51,000 sccm. Non-limiting examples of a total flow rate of the non-reactive fluid and the reactive fluid into the reaction vessel may include about 10 sccm, about 20 sccm, about 50 sccm, about 100 sccm, about 200 sccm, about 500 sccm, about 1,000 sccm, about 2,000 sccm, about 5,000 sccm, about 10,000 sccm, about 20,000 sccm, about 50,000 sccm, about 51,000 sccm, or ranges between any two of these values (including endpoints). In another non-limiting example, the total flow rate of the non-reactive fluid and the reactive fluid into the reaction vessel may be about 5,000 sccm to about 10.00 sccm. In yet another non-limiting example, the total flow rate of the non-reactive fluid and the reactive fluid into the reaction vessel may be about 6818 sccm.

In some embodiments, the non-reactive fluid and the reactive fluid may be introduced into the reaction vessel of the treatment system at a flow rate ratio of non-reactive fluid to reactive fluid of about 10:1 to about 2400:1. Non-limiting examples of flow rate ratio of non-reactive fluid to reactive fluid may include about 10:1, about 20:1, about 50:1, about 100:1, about 200:1, about 500:1, about 1000:1, about 2000:1, about 2400:1, or ranges between any two of these values (including endpoints). In one example, the non-reactive fluid may be argon gas, the reactive fluid may be acetylene, and the flow rate ratio of argon to acetylene may be about 10:1 to about 100:1. Non-limiting examples of a flow rate ratio of argon to acetylene may include about 10:1, about 20:1, about 30:1, about 40:1, about 50:1, about 60:1, about 70:1, about 80:1, about 90:1, about 100:1, or ranges between any two of these values (including endpoints). In one non-limiting example, the flow rate ratio of argon to acetylene may include about 57:1 to about 58:1.

A power supply may be disposed 450 to generate a potential between the tip of the at least one needle and the second electrode in the treatment system, thereby producing an electric field in which the reactive fluid and the non-reactive fluid may be induced to form a plasma. In some embodiments, the power supply may produce a non-varying electrical potential. In other non-limiting embodiment, the power supply may produce an oscillating electrical potential. In a non-limiting example of the oscillating electrical potential embodiment, the second electrode may be in electrical communication with the power supply ground, while the tip of the at least one conductive needle may be in electrical communication with the power supply oscillating voltage output. In such a configuration, the second electrode may act as a grounding shield for the sample located distal to the second electrode. As a result, the sample may be protected from both a high potential field as well as ionized species produced in the plasma. Additionally, an oscillating electrical field configuration may reduce spark formation between the tip of the at least one conductive needle and the second electrode. Experimental observations have indicated that the treatment system may demonstrate more stable operation using an oscillating electric field compared to a non-varying electric field. Without being bound by theory, it appears that an oscillating electrical potential applied to the tip of the at least one conductive needle may prevent charge build up for example on the insulating walls of the reaction vessel, thereby reducing spark generation.

The reactive fluid may be exposed 460 to the electric potential, thereby forming a treatment material that may include electrically neutral free radicals. At least one surface of the substrate may be contacted 470 with the treatment material, thereby treating the substrate. It may be understood that the fluid pressure within the reaction vessel, due at least in part to the non-reactive fluid and the reactive fluid, may be about equal to ambient gas pressure.

Depending on the nature or type of the reactive fluid and the non-reactive fluid, the substrate surface may be treated in any number of ways. Some non-limiting examples of sample surface treatments may include coating at least a portion of the surface, modifying the surface free energy of at least a portion of the surface, and changing the surface density of nucleation sites of at least a portion of the surface.

As one example of a treatment, a sample surface may be coated at least in part with a coating material. Substrates that may be coated using a coating treatment may include one or more of an organic material, a metal, a ceramic, a polymer, a cellulosic nanocrystal, a nanoparticle, an asphalt road surface, a concrete surface, a paper, a textile, a thread, a yarn, a crop seed, a chicken egg, a fresh fruit, a fresh vegetable, a meat product, or any combination thereof. In some non-limiting embodiments of a coating treatment, the reactive fluid may be introduced into the reaction vessel at a rate of about 1 sccm to about 1,000 sccm (as disclosed above). In one example of a coating treatment, the reactive fluid may be introduced into the reaction vessel at a rate of about 100 sccm. In some embodiments of a coating treatment, the non-reactive fluid and the reactive fluid may be introduced into the reaction vessel of the treatment system at a flow rate ratio of non-reactive fluid to reactive fluid of about 10 to about 2400 (as disclosed above). In one non-limiting example of a coating treatment, the non-reactive fluid and the reactive fluid may be introduced into the reaction vessel of the treatment system at a flow rate ratio of non-reactive fluid to reactive fluid of about 10 to about 100 (as disclosed above). The coating treatment material produced by the plasma may include electrically neutral free radicals.

In a coating treatment, the reactive gas may be a hydrocarbon gas, oxygen gas, sulfur hexafluoride gas, carbon tetrafluoride gas, aniline vapor, hexadimethyldisiloxane vapor, di(ethylene glycol) vinyl ether vapor, or any combination thereof. In one non-limiting example, the reactive gas may be acetylene. Treatment materials that may be generated by acetylene may include, without limitation, an ethynyl radical, a vinyl radical, an ethyl radical, a methyl radical, and any combination thereof. Coatings produced by the use of other reactive hydrocarbon gases may include polymer films or nodules. In a coating treatment, the substrate may be exposed to a coating treatment material for about 0.01 hours to about 1 hour. Non-limiting examples of a treatment material exposure time may include about 0.01 hours, about 0.02 hours, about 0.05 hours, about 0.1 hours, about 0.2 hours, about 0.5 hours, about 1 hours, or ranges between any two of these values (including endpoints). In one non-limiting example of a coating treatment, the substrate may be exposed to a coating treatment material for about 0.5 hour. In another non-limiting example of a coating treatment, the substrate may be exposed to a coating treatment material for about 1 hour. In yet another non-limiting example of a coating treatment, the substrate may be exposed to a coating treatment material for 30 minutes to about 70 minutes. Non-limiting examples of a treatment time may include about 30 minutes, about 40 minutes, about 50 minutes, about 60 minutes, about 70 minutes, or ranges between any two of these values (including endpoints).

In a coating treatment, at least a portion of the surface of the substrate may be coated. In some non-limiting examples, the coating may form a generally continuous layer over the treatment surface. A generally continuous surface coating on the substrate may have a thickness of about 0.01 μm to about 100 μm. Non-limiting examples of a surface coating thickness may include about 0.01 μm, about 0.02 μm, about 0.05 μm, about 0.1 μm, about 0.2 μm, about 0.5 μm, about 1.0 μm, about 2.0 μm, about 5.0 μm, about 10 μm, about 20 μm, about 50 μm, about 100 μm, or ranges between any two of these values (including endpoints). In other non-limiting examples, the coating may result in a discontinuous deposition of treatment material on the sample surface, resulting in a non-continuous layer of coating. Discontinuous surface coatings may include small surface projectiles, such as adherent spheres, linear patches, irregularly edged patches, nodules, patches, and nucleation sites, or any combination thereof.

A composite composition may be fabricated using surface treated substrates contacted with a polymer matrix. Coatable substrates that may be used in composite compositions may include, without limitation, particulates, threads, yarns, textiles, papers, sheets, and combinations thereof. The surface treated substrates may be disposed randomly within the polymer matrix and/or aligned within the polymer matrix. A composite composition may include more than one type of surface treated substrate.

The polymer matrix of the composite may include thermoset and thermoplastic polymers including, but not limited to, a polyester, a vinyl-ester, an epoxy, a phenol-formaldehyde, a polyurethane, a bis-maleimide, a polyamide, a poly(ether imide), a polyamide imide, a poly(phenylene sulfide), a poly(ether-ether ketone), a polyethylene, a polypropylene, a styrene, a vinyl chloride, a polyethylene terephthalate, or any combination thereof.

Surface treatments may include coating the substrate with a treatment material such as a hydrophobic surface coating. In some non-limiting embodiments, the surface treated substrates may include surface treated particulates. The surface treatment of the particulates may result in hydrophobically coated particulates.

The surface treated substrates may be coated with a continuous or discontinuous layer of a treatment material. In some non-limiting embodiments, the treatment material may be a hydrocarbon polymer that may be generated by exposing the substrates to a treatment material generated by an atmospheric pressure weakly ionized plasma. The treatment material may include electrically neutral reactive fluid radicals derived from a reactive fluid exposed to the atmospheric pressure weakly ionized plasma. In one non-limiting example, the substrate may include wood flour grains and the reactive fluid may be acetylene.

### EXAMPLES

### Example 1

### Materials Produced by a Coating Treatment Process

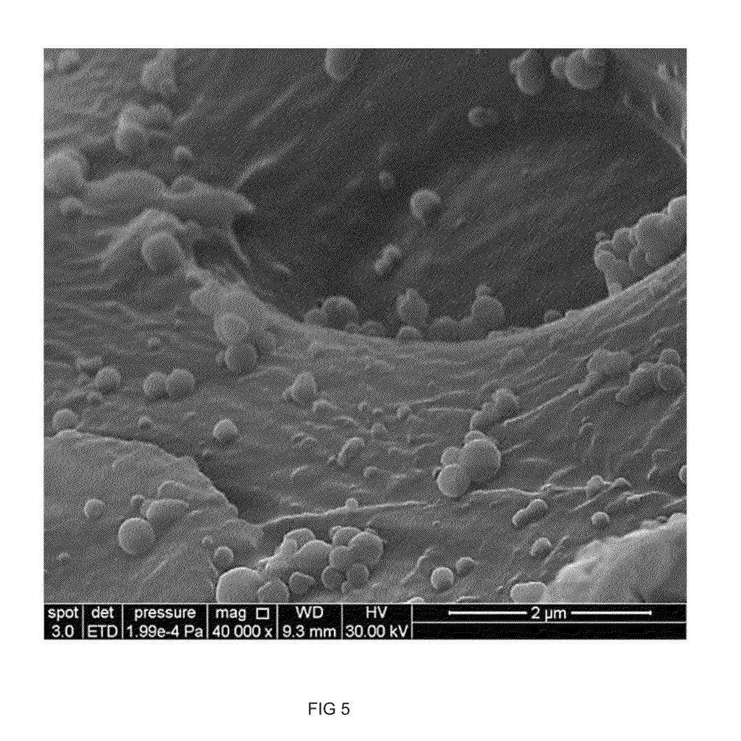

FIG. 5 depicts a photomicrograph of a material treated with a coating process in a treatment system as disclosed above.

The treatment system used for the material included a first electrode composed of an array of seven stainless steel needles, six needles arrayed in a 2.5 cm radius circle and the seventh needle placed in the center. The radius of curvature of the tips of each needle was about 40 μm to about 45 μm. The base of each needle was surrounded by four vents each having a diameter of about 3 mm to ensure gases flow into the gap. The second electrode was composed of a stainless steel mesh with 70% open area. Both the first electrode and the second electrode were secured by non-conductive holders fitted to the inner surface of the wall of the reactor vessel, thereby tightly seating the electrodes.

The proximal end of the reaction vessel included two inlets for the gases. An exhaust outlet was also provided at the distal end of the reaction vessel. The power supply produced an AC electric potential of about 60 Hz frequency at about 5 kV RMS between the first electrode and the second electrode. The non-reactive fluid used in the treatment process was about 99.996% pure argon and was delivered into the reaction vessel at a flow rate of about 2.0 l/min (2000 cm³/min at standard temperature and pressure). The reactive fluid used in the treatment process was about 98.0% pure acetylene, and was delivered into the reaction vessel at a rate of about 15 cm³/min at standard temperature and pressure. The substrate depicted in FIG. 5 was composed of wood flour derived from Eastern White Pine (Pinus strobus). The wood flour was sieved through a USA standard test sieve having an average pore size of about 100 μm. The wood flour was placed in a fluidizer unit maintained at a distance of about 1 cm to about 1.5 cm distal to the second electrode. The fluidizer was used to expose a maximum amount of wood flour surface area to the treatment material generated by the treatment system. The wood flour substrate was exposed to the treatment material for up to 50 minutes.

The image depicted in FIG. 5 is a photomicrograph taken by a scanning electron microscope and depicts a portion of a surface of a wood flour grain at a magnification of about 40,000. A plurality of spherical nodules having an average diameter of about 300 nm±about 40 nm may be observed on the surface of the grain. A capillary diffusion test using the treated wood flour demonstrated that the diffusion of liquid water through a capillary filled with treated wood flour decreased linearly with increasing treatment time of the wood flour. Such data indicated that the surfaces of the wood flour became more hydrophobic as the wood flour was exposed to the treatment material. Increased surface hydrophobicity may improve the ability of a treated material to be incorporated into a hydrophobic matrix, for example of a plastic.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated in this disclosure, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used in this disclosure is for the purpose of describing particular embodiments only, and is not intended to be limiting.

With respect to the use of substantially any plural and/or singular terms in this disclosure, those having skill in the art can translate from the plural to the singular and/or from the singular to the plural as is appropriate to the context and/or application. The various singular/plural permutations may be expressly set forth in this disclosure for sake of clarity.

It will be understood by those within the art that, in general, terms used in this disclosure, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed in this disclosure also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed in this disclosure can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. From the foregoing, it will be appreciated that various embodiments of the present disclosure have been described for purposes of illustration, and that various modifications may be made without departing from the scope and spirit of the present disclosure. Accordingly, the various embodiments disclosed are not intended to be limiting, with the true scope and spirit being indicated by the following claims.

1. A system to treat a substrate, the system comprising:
a reaction vessel comprising a proximal end and a distal end;
a source of a non-reactive fluid in fluid communication with the proximal end of the reaction vessel;
a source of a reactive fluid in fluid communication with the proximal end of the reaction vessel;
a first electrode disposed within the proximal end of the reaction vessel and comprising at least one needle having at least one needle tip, wherein the at least one needle tip is disposed towards the distal end of the reaction vessel;
a second electrode comprising a mesh screen disposed within the reaction vessel and distal to the at least one needle tip, to define a gap between the at least one needle tip and the second electrode, wherein the mesh screen comprises at least one electrically conductive wire;
a power supply in electrical communication with the at least one needle tip and the at least one electrically conductive wire of the second electrode, the power supply configured to:
produce an electrical potential between the at least one needle tip and the second electrode, and
provide a power supply ground to the second electrode through the at least one electrically conductive wire; and
a substrate holder disposed within the reaction vessel and distal to the second electrode.

2.-4. (canceled)

5. The system of claim 1, wherein the reaction vessel further comprises:
at least one inlet port at the proximal end in fluid communication with the source of the non-reactive fluid; and
at least one inlet port at the proximal end in fluid communication with the source of the reactive fluid.

6. (canceled)

7. The system of claim 1, wherein the reaction vessel further comprises at least one inlet port at the proximal end in fluid communication with the source of the non-reactive fluid and the source of the reactive fluid.

8. The system of claim 1, wherein the first electrode further comprises an electrically conductive surface in electrical communication with the at least one needle.

9.-11. (canceled)

12. The system of claim 8, wherein the at least one needle is in electrical communication with an at least one electrically conductive needle rod, and the at least one electrically conductive needle rod is in electrical communication with the conductive surface.

13. (canceled)

14. (canceled)

15. The system of claim 8, wherein the conductive surface comprises at least one vent configured to permit passage of one or more of the reactive fluid and the non-reactive fluid therethrough.

16.-24. (canceled)

25. The system of claim 1, wherein the surface of the at least one needle tip is metallic.

26. The system of claim 25, wherein the surface of the at least one needle tip is nickel-plated steel.

27. The system of claim 1, wherein the gap has a distance of about 1 cm to about 20 CM.

28. (canceled)

29. The system of claim 1, wherein the second electrode further comprises a ring, the ring comprising a rounded surface directed toward the gap.

30.-32. (canceled)

33. The system of claim 1, wherein the mesh screen has a porosity of about 40% to about 90%.

34. (canceled)

35. The system of claim 1, wherein the power supply is configured to generate an oscillating electrical potential between the at least one needle tip and the second electrode.

36. The system of claim 35, wherein the power supply is configured to generate the oscillating electrical potential of about 1.2 kV RMS to about 15 kV RMS between the at least one needle tip and the second electrode, and wherein the oscillating electrical potential has a frequency of about 50 Hz to about 60 Hz.

37.-43. (canceled)

44. The system of claim 1, further comprising a motion system configured to move the substrate holder in at least one of a vertical direction and a horizontal direction relative to the second electrode.

45. (canceled)

46. The system of claim 1, further comprising:
at least one controllable mechanism configured to:
convey an amount of the non-reactive fluid into the proximal end of the reaction vessel, and
convey an amount of the reactive fluid into the proximal end of the reaction vessel.

47. (canceled)

48. The system of claim 1, wherein the reaction vessel further comprises:
a sealable access opening proximate to the substrate holder, and
an exhaust outlet proximate to the distal end.

49. (canceled)

50. A method to treat a substrate, the method comprising:
providing a system to treat a substrate comprising:
a reaction vessel comprising a proximal end and a distal end,
a source of a non-reactive fluid in fluid communication with the proximal end of the reaction vessel,
a source of a reactive fluid in fluid communication with the proximal end of the reaction vessel,
a first electrode disposed within the proximal end of the reaction vessel and comprising at least one needle having at least one needle tip, wherein the at least one needle tip is disposed towards the distal end of the reaction vessel,
a second electrode comprising a mesh screen disposed within the reaction vessel and distal to the at least one needle tip, to define a gap between the at least one needle tip and the second electrode, wherein the mesh screen comprises at least one electrically conductive wire,
a power supply in electrical communication with the at least one needle tip and the at least one electrically conductive wire of the second electrode, the power supply configured to:
produce an electrical potential between the at least one needle tip and the second electrode, and
provide a power supply ground to the second electrode through the at least one electrically conductive wire, and
a substrate holder disposed within the reaction vessel and distal to the second electrode;
contacting the substrate with the substrate holder;
introducing the non-reactive fluid into the reaction vessel from the source of the non-reactive fluid;
introducing the reactive fluid into the reaction vessel from the source of the reactive fluid;
causing the power supply to develop the electrical potential between the at least one needle tip and the second electrode;
exposing at least the reactive fluid to the electrical potential, thereby producing a treatment material; and
contacting a surface of the substrate with the treatment material, thereby treating the substrate,
wherein a fluid pressure within the reaction vessel due at least in part to the non-reactive fluid and the reactive fluid therein is about equal to an ambient gas pressure.

51. The method of claim 50, wherein introducing the non-reactive fluid comprises introducing argon, helium, neon, or any combination thereof.

52. (canceled)

53. (canceled)

54. The method of claim 50, wherein introducing the reactive fluid comprises introducing a hydrocarbon gas, oxygen gas, sulfur hexafluoride gas, carbon tetrafluoride gas, aniline vapor, hexadimethyldisiloxane vapor, di(ethylene glycol) vinyl ether vapor, acetylene, or any combination thereof.

55.-58. (canceled)

59. The method of claim 50, wherein:
introducing the non-reactive fluid comprises introducing argon; and
introducing the reactive fluid comprises introducing acetylene.

60. The method of claim 50, wherein:
introducing the non-reactive fluid comprises introducing argon; and
introducing the reactive fluid comprises introducing oxygen.

61. The method of claim 50, wherein producing the treatment material comprises producing one or more neutral free radicals.

62. The method of claim 50, wherein treating the substrate comprises one or more of coating at least a portion of the surface of the substrate, modifying a surface free energy of at least the portion of the surface of the substrate, and changing a surface density of nucleation sites of at least the portion of the surface of the substrate.

63. (canceled)

64. The method of claim 50, wherein:
introducing the reactive fluid comprises introducing a hydrocarbon gas, oxygen gas, sulfur hexafluoride gas, carbon tetrafluoride gas, aniline vapor, hexadimethyldisiloxane vapor, di(ethylene glycol) vinyl ether vapor, or any combination thereof; and
treating the substrate comprises coating at least a portion of the surface of the substrate with the treatment material.

65. The method of claim 64, wherein treating the substrate comprises coating at least the portion of the surface of the substrate with one or more of an organic material, a metal, a ceramic, a polymer, a cellulosic nanocrystal, a nanoparticle, an asphalt road surface, a concrete surface, a paper, a textile, a thread, a yarn, a crop seed, a chicken egg, a fresh fruit, a fresh vegetable, and a meat product.

66. The method of claim 64, wherein coating at least the portion of the surface of the substrate with the treatment material comprises coating at least the portion of the surface of the substrate with a continuous layer of the treatment material.

67. (canceled)

68. The method of claim 64, wherein coating at least the portion of the surface of the substrate with the treatment material comprises coating at least the portion of the surface of the substrate with a non-continuous layer of one or more of nodules, patches, and threads.

69. (canceled)

70. The method of claim 50, further comprising causing the substrate to move with respect to the second electrode.

71.-75. (canceled)

76. A method to fabricate a system to treat a substrate, the method comprising:
providing a reaction vessel comprising a proximal interior end and a distal interior end;
contacting a first electrode comprising at least one needle having at least one needle tip within the proximal interior of the reaction vessel, wherein the at least one needle tip is directed towards the distal interior end of the reaction vessel;
contacting a second electrode within the distal interior end of the reaction vessel, to form a gap between the at least one needle tip and a mesh screen within the second electrode, wherein the mesh screen comprises at least one electrically conductive wire;
disposing a substrate holder within the distal interior end of the reaction vessel, wherein the substrate holder is distal to the second electrode;
providing a power supply in electrical communication with the at least one needle tip and the at least one electrically conductive wire of the second electrode, the power supply configured to:
produce an electrical potential between the at least one needle tip and the second electrode, and
provide a power supply ground to the second electrode through the at least one electrically conductive wire;
providing at least one fluid inlet port in fluid communication with the proximal interior end of the reaction vessel; and
providing at least one exhaust outlet in fluid communication with the distal interior end of the reaction vessel.

77. The method of claim 76, wherein contacting the first electrode comprising at least one needle having at least one needle tip with the proximal interior end of the reaction vessel comprises forming a fluid-tight seal between the first electrode comprising at least one needle having at least one needle tip and the proximal interior end of the reaction vessel.

78. The method of claim 76, wherein contacting the second electrode with the distal interior end of the reaction vessel comprises forming a fluid-tight seal between the second electrode and the distal interior end of the reaction vessel.

79. The method of claim 76, further comprising providing a sealable access opening proximate to the substrate holder.
